(19) United States
(12) Patent Application Publication
(10) Pub. No.: US 2026/0282767 A1
(43) Pub. Date: Sep. 17, 2026

(54) SYNAPTIC DEVICE AND SYNAPTIC DEVICE ARRAY

(71) Applicant: Hong Kong Metropolitan University, Hong Kong (CN)

(72) Inventors: Dani Samer Assi, Hong Kong (CN); Arul Lenus Roy Vellaisamy, Hong Kong (CN); Hongli Huang, Hong Kong (CN); Vaithinathan Karthikeyan, Hong Kong (CN)

(21) Appl. No.: 19/079,584

(22) Filed: Mar. 14, 2025

(51) Int. Cl. H10N 70/00; G06N 3/063; H10B 63/00; H10N 70/20; H10N 79/00; H10N 99/00

(52) U.S. Cl. CPC H10N 70/8828; G06N 3/063; H10B 63/22; H10N 70/20; H10N 79/00; H10N 99/05

(57) ABSTRACT

A synaptic device and a synaptic device array. The synaptic device includes a first electrode, a second electrode, and a topological insulator operably coupled between the first electrode and the second electrode. The topological insulator may be a quantum topological insulator. The synaptic device array includes multiple ones of the synaptic device.

### TECHNICAL FIELD

This invention relates to a synaptic device and a synaptic device array.

### BACKGROUND

Synaptic devices are devices arranged to imitate the function of biological synapses in the brain, and they can be used in various application including brain-computer interfaces (BCIs), artificial intelligence (AI), neuromorphic computing, etc.

In practice, it would be difficult if not impossible for synaptic devices to fully replicate the capability of biological synapses in terms of adaptability, efficiency, and complexity. Yet, there remains a need to provide synaptic devices that can better match the capability of biological synapses in one or more aspects.

### SUMMARY

In a first aspect, there is provided a synaptic device. The synaptic device comprises a first electrode, a second electrode, and a topological insulator operably coupled between the first electrode and the second electrode.

In one embodiment of the first aspect, the topological insulator is a quantum topological insulator.

In one embodiment of the first aspect, the topological insulator is in the form of a thin film.

In one embodiment of the first aspect, the topological insulator is deposited or electroplated on the first electrode.

In one embodiment of the first aspect, the topological insulator comprises a bismuth-based topological insulator made of bismuth-based material (e.g., bismuth-based compound). For example, the bismuth-based material may include bismuth chalcogenide. For example, the bismuth-based material may comprise or consist essentially of bismuth selenide telluride (Bi₂Se₂Te). For example, the bismuth-based material may comprise or consist essentially of bismuth selenide (Bi₂Se₃). For example, the bismuth-based material may comprise or consist essentially of bismuth telluride (Bi₂Te₃).

In one embodiment of the first aspect, the topological insulator comprises a tin-based topological insulator made of tin-based material (e.g., tin-based compound). For example, the tin-based material may include tin chalcogenide. For example, the tin-based material may comprise or consist essentially of tin telluride (SnTe). For example, the tin-based material may comprise or consist essentially of tin selenide (SnSe). For example, the tin-based material may comprise or consist essentially of tin selenide telluride (SnSeTe).

In one embodiment of the first aspect, the topological insulator comprises an antimony-based topological insulator made of antimony-based material (e.g., antimony-based compound). For example, the antimony-based material may include antimony chalcogenide. For example, the antimony-based material may comprise or consist essentially of antimony telluride (Sb₂Te₃). For example, the antimony-based material may comprise or consist essentially of antimony selenide (Sb₂Se₃). For example, the antimony-based material may comprise or consist essentially of antimony selenide telluride (SbSeTe).

In one embodiment of the first aspect, the topological insulator is made of binary semiconductor material (e.g., binary semiconductor compound). For example, the binary semiconductor material may comprise or consist essentially of lead telluride (PbTe). For example, the binary semiconductor material may comprise or consist essentially of lead selenide (PbSe). For example, the binary semiconductor material may comprise or consist essentially of mercury telluride (HgTe). For example, the binary semiconductor material may comprise or consist essentially of cadmium arsenide (Cd₃As₂).

In one embodiment of the first aspect, the topological insulator is made from a material that comprises or consists essentially of one or more of: bismuth selenide telluride (Bi₂Se₂Te), bismuth selenide (Bi₂Se₃), bismuth telluride (Bi₂Te₃), tin telluride (SnTe), tin selenide (SnSe), tin selenide telluride, (SnSeTe), antimony telluride (Sb₂Te₃), antimony selenide (Sb₂Se₃), antimony selenide telluride (SbSeTe), lead telluride (PbTe), lead selenide (PbSe), mercury telluride (HgTe), cadmium arsenide (Cd₃As₂) or any combination thereof.

In one embodiment of the first aspect, the first electrode comprises an electrical conductor made of an electrically conductive oxide. For example, the electrically conductive oxide may comprise or consist essentially of transparent conductive oxide. For example, the electrically conductive oxide may comprise or consist essentially of fluorine-doped tin oxide (FTO). In one embodiment, the electrically conductive oxide is arranged on a substrate. For example, the substrate may comprise or consist essentially of a glass substrate.

In one embodiment of the first aspect, the second electrode comprises an electrical conductor made of metal. For example, the metal may comprise or consist essentially of silver.

In one embodiment of the first aspect, the first electrode comprises an electrical conductor made of an electrically conductive oxide, the second electrode comprises an electrical conductor made of metal, and the topological insulator comprises a bismuth-based topological insulator made of bismuth-based material (e.g., bismuth-based compound). For example, the first electrode may comprise an electrical conductor made of an electrically conductive oxide that comprises or consists essentially of FTO, the second electrode may comprise an electrical conductor made of metal that comprises or consists essentially of silver, and the topological insulator comprises a bismuth-based topological insulator made of bismuth-based material such as Bi₂Se₂Te, Bi₂Se₃, or Bi₂Te₃.

In one embodiment of the first aspect, the synaptic device is a two-terminal synaptic device, with the first electrode emulating a postsynaptic terminal and the second electrode emulating a presynaptic terminal. In other words, the synaptic device lacks a further electrode (only has the first and second electrodes).

In one embodiment of the first aspect, the first electrode is arranged to emulate a postsynaptic terminal, the second electrode is arranged to emulate a presynaptic terminal, and the synaptic device is operable to neuromodulate synaptic response characteristics by dynamically adjusting a signal transmission efficiency between the presynaptic terminal and the postsynaptic terminal in response to receiving an applied stimulation signal.

In one embodiment of the first aspect, the synaptic device is arranged to operate as a neuromodulator (i.e., the synaptic device is operable to perform neuromodulation).

In one embodiment of the first aspect, the synaptic device is operable to dynamically adjust a synaptic conductance state for performing neuromodulation. For example, the neuromodulation may be performed based at least in part on a modulation index derived from a ratio between a change in synaptic conductance and a reference synaptic conductance.

In one embodiment of the first aspect, the synaptic device is operable to emulate a synaptic plasticity mechanism. For example, the synaptic plasticity mechanism may comprise at least one of: paired-pulse facilitation (PPF), Paired-Pulse Depression (PPD), post-tetanic potentiation (PTP), post-tetanic depression (PTD), short-term plasticity (STP), short-term depression (STD), long-term potentiation (LTP), long-term depression (LTD), excitatory postsynaptic current (EPSC), inhibitory postsynaptic current (IPSC), or spike-rate dependent plasticity (SRDP).

In one embodiment of the first aspect, the synaptic device is operable to dynamically adjust synaptic weight in response to receiving a stimulation signal.

In one embodiment of the first aspect, the synaptic device is arranged for brain-computer interface application (e.g., brain-computer interface for neuro-prosthetics).

In a second aspect, there is provided a synaptic device array that comprises a plurality of synaptic devices of the first aspect. The plurality of synaptic devices may be arranged in an array with N row(s) and M column(s), where N and M are integers and N+M>2.

In a third aspect, there is provided a method of making a synaptic device. The method comprises depositing a topological insulator material on a first electrode. and arranging a second electrode on the deposited topological insulator material, thereby forming a synaptic device. The synaptic device may be the synaptic device of the first aspect. The depositing may be performed by electrochemical deposition. The topological insulator material may comprise at least one of: bismuth-based material, antimony-based material, tin-based material, etc. The method may belong to a method of making a synaptic device array.

Other features and aspects will become apparent by consideration of the following detailed description and the accompanying drawings. Any feature(s) described herein in relation to one aspect or embodiment may be combined with any other feature(s) described herein in relation to any other aspect or embodiment, as appropriate and applicable.

### BRIEF DESCRIPTION OF THE DRAWINGS

Some embodiments will now be described, with reference to the accompanying drawings, in which:

FIG. 1 is a schematic diagram illustrating a synaptic device in one embodiment;

FIG. 2 is a schematic diagram illustrating fabrication of a synaptic neuroelectronic device in one embodiment;

FIG. 3A is a schematic diagram illustrating the structure of bismuth selenide telluride (Bi₂Se₂Te) thin film in the synaptic neuroelectronic device of FIG. 2;

FIG. 3B is a graph showing X-ray diffraction (XRD) analysis results of the Bi₂Se₂Te thin film in the synaptic neuroelectronic device of FIG. 2;

FIG. 3C is a graph showing a Raman scattering plot of the Bi₂Se₂Te thin film in the synaptic neuroelectronic device of FIG. 2;

FIG. 3D is a field emission scanning electron microscope (FE-SEM) micrograph of the Bi₂Se₂Te thin film in the synaptic neuroelectronic device of FIG. 2;

FIG. 3E is an atomic force microscope (AFM) profile of the Bi₂Se₂Te thin film in the synaptic neuroelectronic device of FIG. 2;

FIG. 3F is a Raman mapping showing homogenous distribution of the Bi₂Se₂Te thin film in the synaptic neuroelectronic device of FIG. 2;

FIG. 4 is a graph showing XRD analysis results for Bi₂Se₃, Bi₂Te₃, or Bi₂Se₂Te in some embodiments;

FIG. 5A is a FE-SEM micrograph of a Bi₂Se₃ thin film and its elemental mapping distribution in one embodiment;

FIG. 5B is a FE-SEM micrograph of a Bi₂Se₂Te thin film and its elemental mapping distribution in one embodiment;

FIG. 5C is a FE-SEM micrograph of a Bi₂Te₃ thin film and its elemental mapping distribution in one embodiment;

FIG. 6A an AFM profile of the Bi₂Se₃ thin film of FIG. 5A;

FIG. 6B an AFM profile of the Bi₂Se₂Te thin film of FIG. 5B;

FIG. 6C an AFM profile of the Bi₂Te₃ thin film of FIG. 5C;

FIG. 7 is a schematic diagram illustrating topological surface edge state changes induced by an applied electric field in Bi₂Se₂Te in one embodiment;

FIG. 8 is a schematic diagram illustrating a simulated charge density distribution in conduction band minimum and electron localization along the plane of Bi₂Se₂Te under different applied electric fields in one embodiment;

FIG. 9A is a graph showing the current-voltage characteristics of a Bi₂Se₂Te synaptic device in one embodiment;

FIG. 9B is a graph showing the change in impedance state of the Bi₂Se₂Te synaptic device under different applied voltages;

FIG. 10A is a graph showing the current-voltage characteristics of a Bi₂Se₃ synaptic device in one embodiment;

FIG. 10B is a graph showing the current-voltage characteristics of the Bi₂Se₃ synaptic device with regions associated with different conduction mechanisms;

FIG. 10C is a graph showing the current-voltage characteristics of the Bi₂Se₃ synaptic device based on a space charge limited current (SCLC) conduction mechanism (i.e., SCLC model);

FIG. 10D is a graph showing the current-voltage characteristics of the Bi₂Se₃ synaptic device based on a trapped charge limited current (TCLC) conduction mechanism (i.e., TCLC model);

FIG. 10E is a graph showing the resistance of high resistance state (R_{HRS}) and the resistance of low resistance state (R_{LRS}) against different number of switching cycles for the Bi₂Se₃ synaptic device;

FIG. 10F is a graph showing the resistance of high resistance state (R_{HRS}) and the resistance of low resistance state (R_{LRS}) against time for the Bi₂Se₃ synaptic device;

FIG. 11A is a graph showing the current-voltage characteristics of a Bi₂Se₂Te synaptic device in one embodiment;

FIG. 11B is a graph showing the current-voltage characteristics of the Bi₂Se₂Te synaptic device with regions associated with different conduction mechanisms;

FIG. 11C is a graph showing the current-voltage characteristics of the Bi₂Se₂Te synaptic device based on a space charge limited current (SCLC) conduction mechanism (i.e., SCLC model);

FIG. 11D is a graph showing the current-voltage characteristics of the Bi₂Se₂Te synaptic device based on a trapped charge limited current (TCLC) conduction mechanism (i.e., TCLC model);

FIG. 11E is a graph showing the resistance of high resistance state (R_{HRS}) and the resistance of low resistance state (R_{LRS}) against different number of switching cycles for the Bi₂Se₂Te synaptic device;

FIG. 11F is a graph showing the resistance of high resistance state (R_{HRS}) and the resistance of low resistance state (R_{LRS}) against time for the Bi₂Se₂Te synaptic device;

FIG. 12A is a graph showing the current-voltage characteristics of a Bi₂Te₃ synaptic device in one embodiment;

FIG. 12B is a graph showing the current-voltage characteristics of the Bi₂Te₃ synaptic device with regions associated with different conduction mechanisms;

FIG. 12C is a graph showing the current-voltage characteristics of the Bi₂Te₃ synaptic device based on a space charge limited current (SCLC) conduction mechanism (i.e., SCLC model);

FIG. 12D is a graph showing the current-voltage characteristics of the Bi₂Te₃ synaptic device based on a trapped charge limited current (TCLC) conduction mechanism (i.e., TCLC model);

FIG. 12E is a graph showing the resistance of high resistance state (R_{HRS}) and the resistance of low resistance state (R_{LRS}) against different number of switching cycles for the Bi₂Te₃ synaptic device;

FIG. 12F is a graph showing the resistance of high resistance state (R_{HRS}) and the resistance of low resistance state (R_{LRS}) against time for the Bi₂Te₃ synaptic device;

FIG. 13A is a schematic diagram illustrating a pulse width modulated presynaptic voltage stimuli for a Bi₂Se₂Te based synaptic neuroelectronic device in one embodiment;

FIG. 13B is a graph showing the postsynaptic current response change with ageing process of human brain and their corresponding learning efficiency;

FIG. 13C is a graph showing an experimental postsynaptic current response of excitatory postsynaptic current (I_{EPS}) and inhibitory postsynaptic current (I_{IPS}) for different presynaptic stimuli ratios for the Bi₂Se₂Te based synaptic neuroelectronic device;

FIG. 13D is a graph showing the paired-pulse facilitation (PPF) index and paired-pulse depression (PPD) index for different presynaptic stimuli ratios for the Bi₂Se₂Te based synaptic neuroelectronic device;

FIG. 13E is a graph showing the post-tetanic potentiation (PTP) index and post-tetanic depression (PTD) index for different presynaptic stimuli ratios for the Bi₂Se₂Te based synaptic neuroelectronic device;

FIG. 13F is a graph showing the relaxation times for different I_{EPS} and I_{IPS} levels, with respect to the applied stimuli, for the Bi₂Se₂Te based synaptic neuroelectronic device;

FIG. 14A is a schematic diagram illustrating a pulse width modulated presynaptic voltage stimuli for a Bi₂Se₃ based synaptic neuroelectronic device in one embodiment;

FIG. 14B is a graph showing the postsynaptic current response change with ageing process of human brain and their corresponding learning efficiency;

FIG. 14C is a graph showing an experimental postsynaptic current response of I_{EPS} and I_{IPS} for different presynaptic stimuli ratios for the Bi₂Se₃ based synaptic neuroelectronic device;

FIG. 14D is a graph showing the PPF index and PPD index for different presynaptic stimuli ratios for the Bi₂Se₃ based synaptic neuroelectronic device;

FIG. 14E is a graph showing the PTP index and PTD index for different presynaptic stimuli ratios for the Bi₂Se₃ based synaptic neuroelectronic device;

FIG. 14F is a graph showing the relaxation times for different I_{EPS} and I_{IPS} levels, with respect to the applied stimuli, for the Bi₂Se₃ based synaptic neuroelectronic device;

FIG. 15A is a schematic diagram illustrating a pulse width modulated presynaptic voltage stimuli for a Bi₂Te₃ based synaptic neuroelectronic device in one embodiment;

FIG. 15B is a graph showing the postsynaptic current response change with ageing process of human brain and their corresponding learning efficiency;

FIG. 15C is a graph showing an experimental postsynaptic current response of I_{EPS} and I_{IPS} for different presynaptic stimuli ratios for the Bi₂Te₃ based synaptic neuroelectronic device;

FIG. 15D is a graph showing the PPF index and PPD index for different presynaptic stimuli ratios for the Bi₂Te₃ based synaptic neuroelectronic device;

FIG. 15E is a graph showing the PTP index and PTD index for different presynaptic stimuli ratios for the Bi₂Te₃ based synaptic neuroelectronic device;

FIG. 15F is a graph showing the relaxation times for different I_{EPS} and I_{IPS} levels, with respect to the applied stimuli, for the Bi₂Te₃ based synaptic neuroelectronic device;

FIG. 16A is a graph showing the relaxation time (decay rate) of the I_{EPS} for different pulse amplitudes for a Bi₂Se₂Te synaptic device in one embodiment;

FIG. 16B is a graph showing the relaxation time (decay rate) of the I_{IPS} for different pulse amplitudes for the Bi₂Se₂Te synaptic device;

FIG. 16C is a graph showing the decay rate for different pulse amplitude modulated presynaptic stimuli for the Bi₂Se₂Te synaptic device;

FIG. 16D is a graph showing the slope index (I_{S}) representing electric field dependent PPF characteristics (EF-PPF) of the synapse for different pulse amplitude modulated presynaptic stimuli for the Bi₂Se₂Te synaptic device;

FIG. 17A is a graph showing the charge concentration of synaptic devices with Bi₂Se₂Te, Bi₂Te₃, and Bi₂Se₃ as active layers respectively in some embodiments;

FIG. 17B is a graph showing the electrical conductivity and effective mass of the synaptic devices with Bi₂Se₂Te, Bi₂Te₃, and Bi₂Se₃ as active layers respectively in some embodiments;

FIG. 18A is a plot showing the energy consumption (standardized) for synaptic devices with Bi₂Se₂Te, Bi₂Te₃, and Bi₂Se₃ as active layers respectively in some embodiments;

FIG. 18B is a graph showing the energy consumption for synaptic devices with Bi₂Se₂Te, Bi₂Te₃, and Bi₂Se₃ as active layers respectively in some embodiments for different number of cycles;

FIG. 19 is a schematic diagram illustrating the application of the synaptic neuroelectronic device of FIG. 2 for real-time neuromodulation of electroencephalography (EEG);

FIG. 20A is a graph showing the EEG data set obtained from different age groups;

FIG. 20B is a graph showing the event related potential (ERP) signals extracted from the EEG data of three different sample subjects;

FIG. 20C is a graph showing the modulation index derived from changing the resistance state of the synaptic neuroelectronic device of FIG. 2;

FIG. 20D is a graph showing the ERP signals for the three different sample subjects reconstructed using the synaptic neuroelectronic device of FIG. 2; and

FIG. 21 is a flowchart illustrating a mathematical modeling of a neuromodulation process in one embodiment.

### DETAILED DESCRIPTION

Aging and genetic-related disorders in the brain may impair the cognitive function of the brain. For example, age-related changes of the brain, including a decreased number of neurons and a reduced neurotransmitter function, may weaken synaptic strength and contribute to neurodegenerative disorders such as Alzheimer's disease, Parkinson's disease, or amnesic cognitive impairment. Due to the complexity of neural synapses, reversing or alleviating these disorders poses a challenge for brain-computer interfaces (BCIs).

Efforts have been made to create an artificial synaptic neuromodulator for a brain-computer interface. Yet, the creation of an artificial synaptic neuromodulator that can match the performance of the brain is a highly complex task, e.g., because the artificial synaptic neuromodulator may have high energy consumption and significant processing latency. These problems may arise from the inherent properties of active materials and the associated device characteristics, which may respond to electrical stimuli in ways that are incompatible with or at least different from the normal function of the brain. It is useful to better understand the synaptic neural process of the brain and to accordingly design devices made of materials suitable for handling synaptic neural events.

The brain marks learning and memory events through the modulation of neural plasticity. Based on the plasticity of these events in neuron clusters, they are categorized into short-term memory (lasting from seconds to minutes) and long-term memory (lasting from hours to days). The modulation of neural plasticity is initiated by an applied electric stimulus, which can be a presynaptic potentiation pulse (+ve) or depression pulse (−ve). To assess the effectiveness of these events, Hebbian techniques such paired-pulse facilitation/depression and post-tetanic potentiation/depression may be used. The interdependence of neuron cluster pathways may greatly influence the effectiveness. For example, short-term plasticity (STP) may play a key role in affecting the stability of long-term plasticity (LTP), and short-term facilitation may lead to a large paired-pulse facilitation (PPF) index. Additionally, the ability of the brain in responding to potentiation and depression stimuli declines with age. Therefore, to mimic these events, specific design of artificial synapses and electronic neuromodulators may be needed.

Embodiments of the invention provide a synaptic device. The synaptic device may be used for one or more applications, such as BCIs, AI, machine learning (ML), robotics, neuromorphic computing, cognitive computing, neuro-prosthetics, etc. In one example application, the synaptic device may be used for BCIs to facilitate communication between the brain and external device(s). In one example application, the synaptic device may be used as part of an artificial neural network or physical neural network. In one example application, the synaptic device may be used for addressing aging and neurological disorder related cognitive function impairments (e.g., loss) in the human brain.

In one embodiment, the synaptic device may be a quantum synaptic device with quantum properties. The synaptic device may have electric field-induced tunable topological surface edge states and quantum switching properties. The synaptic device may be used for artificial synaptic neuromodulation. In one example application, the synaptic device may leverage its unique quantum synaptic properties to neuromodulate distorted neural signals, which may be useful for reversing or ameliorating aging and genetic-related cognitive function impairments (e.g., loss) in the human brain via a brain-computer interface. In one embodiment, the synaptic device may have synaptic neuroelectronic characteristics and may be useful in treating cognitive neural dysfunctions through modulated neuromorphic stimuli. In one embodiment, the synaptic device may be operable as a non-invasive neuroelectronic modulator for BCIs. In one embodiment, the synaptic device may include semiconductor materials with exceptional switching/processing speed and sensitivity to ultra-low processing power. For example, the synaptic device may include quantum topological insulator (QTI) material. The QTI material may possess electric field-induced tunable conduction at edge surface states, which may be useful for neuromorphic artificial synaptic neuromodulation, and topological quantum properties, such as protected edge surface states and ultrafast carrier transport, which may be useful for supporting artificial synapse functions with a large PPF index.

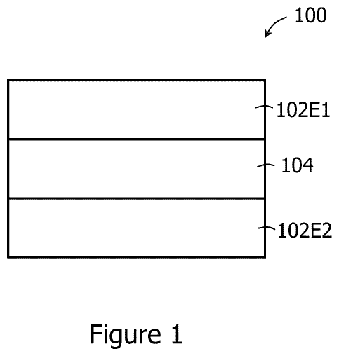

FIG. 1 shows a synaptic device 100 in one embodiment. The synaptic device 100 includes a first electrode 102E1, a second electrode 102E2, and a topological insulator 104 operably coupled between the first and second electrodes 102E1, 102E2. In one example, the first electrode 102E1 may be a top electrode and the second electrode 102E2 may be a bottom electrode. In one example, the first electrode 102E1 may be a bottom electrode and the second electrode 102E2 may be a top electrode. Other orientations are also possible.

The topological insulator 104 may be or include a quantum topological insulator. The quantum topological insulator may have electric field-induced tunable topological surface edge states and one or more quantum properties. The one or more quantum properties may include any one or more of: quantum switching property, protected edge surface states, ultrafast carrier transport, etc. The topological insulator 104 may be deposited or electroplated on the first electrode 102E1 and/or the second electrode 102E2. The topological insulator 104 may be in the form of a thin film. For example, the topological insulator may include a bismuth-based topological insulator made of bismuth-based material such as bismuth chalcogenide. For example, the topological insulator 104 may include a tin-based topological insulator made of tin-based material such as tin chalcogenide. For example, the topological insulator 104 may include an antimony-based topological insulator made of antimony-based material such as antimony chalcogenide. For example, the topological insulator 104 may be made of binary semiconductor material (e.g., binary semiconductor compound). For example, the topological insulator 104 may be made from a material that comprises or consists essentially of one or more of: bismuth selenide telluride (Bi₂Se₂Te), bismuth selenide (Bi₂Se₃), bismuth telluride (Bi₂Te₃), tin telluride (SnTe), tin selenide (SnSe), tin selenide telluride, (SnSeTe), antimony telluride (Sb₂Te₃), antimony selenide (Sb₂Se₃), antimony selenide telluride (SbSeTe), lead telluride (PbTe), lead selenide (PbSe), mercury telluride (HgTe), cadmium arsenide (Cd₃As₂) or any combination thereof. The first electrode 102E1 may include an electrical conductor made of an electrically conductive oxide. For example, the electrically conductive oxide may be or include transparent conductive oxide. For example, the electrically conductive oxide may be or include fluorine-doped tin oxide (FTO). Optionally, the electrically conductive oxide may be arranged on a substrate such as a glass substrate. The second electrode 102E2 may include an electrical conductor made of metal. For example, the metal may be or include silver.

The synaptic device 100 is a multi-terminal synaptic device. In one example, the synaptic device 100 may be a two-terminal synaptic device, with the first electrode 102E1 emulating a postsynaptic terminal and the second electrode 102E2 emulating a presynaptic terminal. Optionally, the synaptic device 100 may include additional electrode(s). For example, the synaptic device 100 may be a three-terminal synaptic device having three terminals.

The synaptic device 100 may be arranged to operate as a neuromodulator (i.e., the synaptic device 100 is operable to perform neuromodulation). The synaptic device 100 may be arranged for brain-computer interface application such as brain-computer interface for neuro-prosthetics.

In one example, the first electrode 102E1 may be arranged to emulate a postsynaptic terminal, the second electrode 102E2 may be arranged to emulate a presynaptic terminal, and the synaptic device 100 may be operable to neuromodulate synaptic response characteristics by dynamically adjusting (e.g., dynamically increasing or decreasing) a signal transmission efficiency between the presynaptic terminal and the postsynaptic terminal in response to receiving an applied stimulation signal (or applied stimuli). In one example, the synaptic device 100 may be operable to dynamically adjust a synaptic conductance state for performing neuromodulation. This may enable real-time regulation of event-related potentials (ERPs) to optimize memory processing, cognitive response, and neural signal restoration. In one example, the neuromodulation process may utilize a modulation index derived from the ratio of between a change in synaptic conductance and a reference synaptic conductance. This may enable precise control of brain signals for cognitive enhancement and may be used for brain-computer interface applications. In one example, the synaptic device 100 may be operable to emulate a synaptic plasticity mechanism. The synaptic plasticity mechanism may include at least one of: paired-pulse facilitation (PPF), Paired-Pulse Depression (PPD), post-tetanic potentiation (PTP), post-tetanic depression (PTD), short-term plasticity (STP), short-term depression (STD), long-term potentiation (LTP), long-term depression (LTD), excitatory postsynaptic current (EPSC), inhibitory postsynaptic current (IPSC), or spike-rate dependent plasticity (SRDP). In one example, the synaptic device 100 may be operable to dynamically adjust synaptic weight in response to receiving a stimulation signal, e.g., to facilitating adaptive learning, memory consolidation, and/or long-term synaptic retention.

The synaptic device 100 may be configured for ultra-low power consumption and hence may be energy efficient. This may be particularly advantageous for applications such as neuromorphic computing, AI processing, or brain-computer interface applications.

The synaptic device 100 may belong to part of a synaptic device array, which includes multiple ones of the synaptic devices 100 optionally arranged in an array. The array may have N row(s) and M column(s), where N and M are integers and N+M>2.

In one example, the synaptic device 100 may be made by a method that includes: depositing a topological insulator material on the first electrode 102E1 and arranging the second electrode 102E2 on the deposited topological insulator material to form the synaptic device 100. For example, the depositing may be performed by electrochemical deposition. For example, the topological insulator material may be or include bismuth-based material.

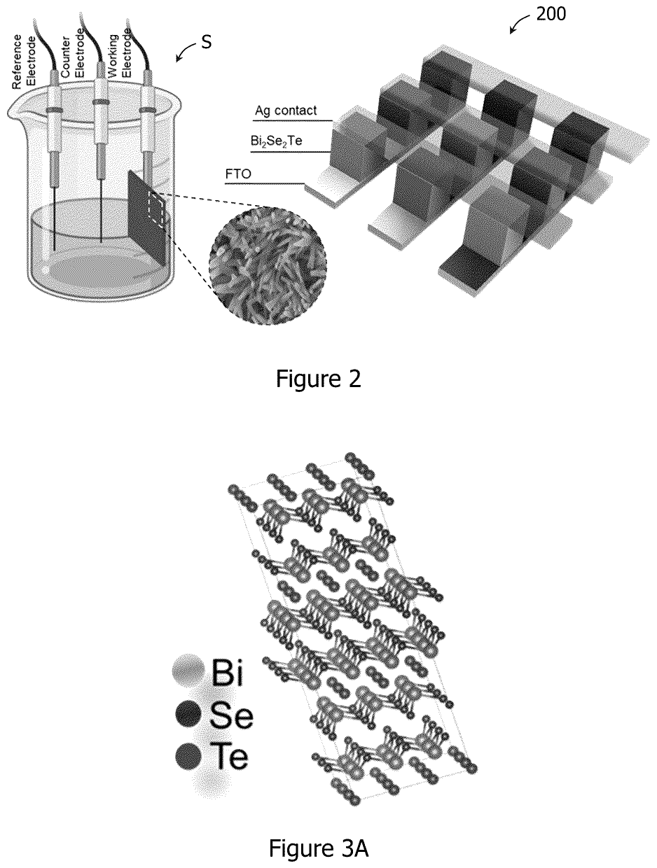

In one embodiment, there is provided a quantum topological synaptic neuroelectronic device 200 (which can be considered as a synaptic device). The synaptic neuroelectronic device 200 is fabricated using an electrochemical deposition method as illustrated in FIG. 2. FIG. 2 shows a set-up S for the electrochemical deposition, and the fabricated synaptic neuroelectronic device 200. To fabricate the synaptic neuroelectronic device 200, an electrochemically optimized material design of Bi₂Se₂Te, which is a QTI material, is deposited on the FTO electrodes. The silver (Ag) electrodes are then arranged on the deposited Bi₂Se₂Te such that the Bi₂Se₂Te is arranged between the Ag electrodes (serving as presynaptic points) and the FTO electrodes (serving as postsynaptic neural points). The deposited Bi₂Se₂Te, schematically illustrated as blocks, is in the form of thin film(s) formed on the FTO electrodes. The synaptic neuroelectronic device 200 in this embodiment may be considered as a synaptic device array with nine synaptic units arranged in an array with three rows and three columns.

Generally, QTI materials belong to special type of semiconducting materials characterized by edge state electronic transport properties that are immune to the backscattering of charges and feature adjustable narrow bandgap edges. These properties arise from their insulating bulk and conducting surface states, leading to ultra-low switching threshold voltage requirements. As QTI materials such as bismuth-based topological materials can meet the requirement for low power and high switching speed, they may be particularly suitable for use in fabricating the synaptic neuroelectronic device.

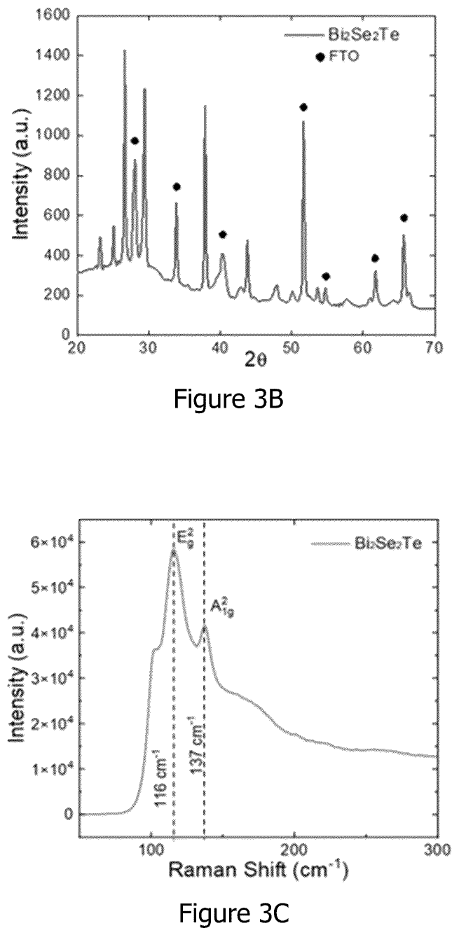

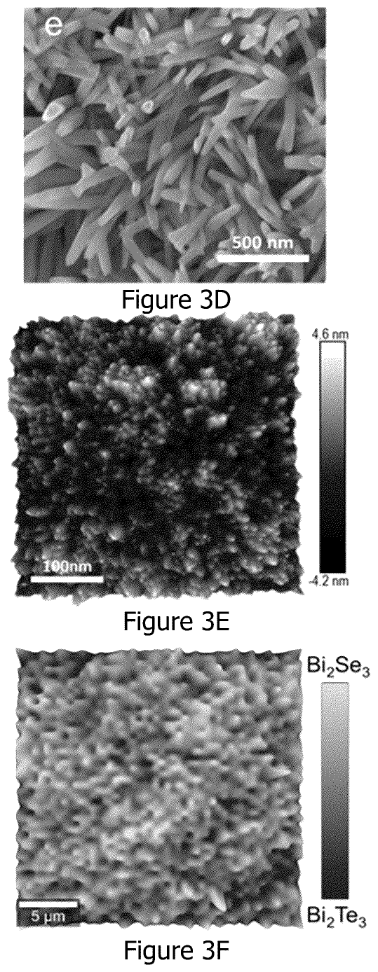

FIG. 3A illustrates the layered 2D crystal structure of the Bi₂Se₂Te thin film in the synaptic neuroelectronic device 200.

FIG. 3B illustrates the X-ray diffraction (XRD) analysis results of the Bi₂Se₂Te thin film in the synaptic neuroelectronic device 200. The XRD analysis demonstrates the characteristic peaks of Bi₂Se₂Te. In this example, the Rigaku Miniflex diffractometer is used for the XRD analysis.

FIG. 3C illustrates the Raman scattering plot of the Bi₂Se₂Te thin film in the synaptic neuroelectronic device 200. The plot illustrates the characteristic

$${E}_{g}^{2} and {A}_{1 g}^{2}$$

peaks associated with Bi₂Se₂Te.

FIG. 3D illustrates the field emission scanning electron microscope (FE-SEM) micrograph of the Bi₂Se₂Te thin film in the synaptic neuroelectronic device 200. It can be seen that the Bi₂Se₂Te thin film has nanorod structures. In this example, the Hitachi SU8240 FE-SEM is used to obtain the micrograph.

FIG. 3E illustrates the atomic force microscope (AFM) profile of the Bi₂Se₂Te thin film in the synaptic neuroelectronic device 200. The roughness topography, i.e., surface roughness, of the Bi₂Se₂Te thin film can be observed. In this example, the Bruker Dimension HPI AFM (scan rate 0.996 Hz) is used to obtain the AFM profile.

FIG. 3F illustrates the Raman mapping of the Bi₂Se₂Te thin film in the synaptic neuroelectronic device 200, which shows the homogenous distribution of the Bi₂Se₂Te thin film. In this example, the Horiba Labram HR Raman System (532 nm laser) is used to obtain the Raman mapping.

In some embodiments, there are provided: a synaptic neuroelectronic device that includes Bi₂Se₃ as QTI material arranged between Ag electrodes (serving as presynaptic points) and FTO electrodes (serving as postsynaptic neural points); a synaptic neuroelectronic device that includes Bi₂Te₃ as QTI material arranged between Ag electrodes (serving as presynaptic points) and FTO electrodes (serving as postsynaptic neural points); and a synaptic neuroelectronic device that includes Bi₂Se₂Te as QTI material arranged between Ag electrodes (serving as presynaptic points) and FTO electrodes (serving as postsynaptic neural points).

In these embodiments, Bi₂Se₃, Bi₂Te₃, and Bi₂Se₂Te are topological insulators and are in the form of thin films. These topological insulator based thin films, i.e., Bi₂Se₃, Bi₂Te₃, and Bi₂Se₂Te thin films, are respectively fabricated on an FTO-coated glass substrate, which is operable to imitate postsynaptic neuron behavior. In each of these embodiments, the functional/active layer of the synaptic device, i.e., the topological insulator based thin film, is deposited utilizing the three-electrode electrochemical deposition technique (uses a counter electrode, a working electrode and a reference electrode, e.g., in set-up S in FIG. 2). Emulation of presynaptic neurons is achieved through the utilization of an Ag electrode (100 nm), fabricated using a thermal evaporation technique. In each of these embodiments, before the deposition, the FTO-coated glass substrate undergoes a cleaning process, which includes sequential immersions in deionized water, acetone, and ethanol within an ultrasonic bath for 30 minutes. The fabrication of the Bi₂Se₃, Bi₂Te₃, and Bi₂Se₂Te active layers is respectively accomplished through the implementation of the electrochemical deposition method, which is conducted using the Metrohm's Autolab PGSTAT302 instrument. In each of these embodiments, an Ag/AgCl double junction reference electrode and a high-purity platinum counter electrode are used to ensure precise monitoring and control of the electrochemical potential throughout the fabrication process. A FTO-coated glass substrate (with an exposed area of 1 cm² and sheet resistance of ≈7 Ωsq⁻¹) is used as the working electrode. Throughout each deposition, the distance between the anode and cathode remains at 0.5 cm.

Using the Bi₂Se₂Te embodiment as an example, the deposition bath in the container (e.g., in set-up S in FIG. 2) includes 50 mL of deionized water (>18 MΩ) sourced from a Purite L300450 water purification system. First, 2.08 mL of HNO₃ is added to the deionized water solution, resulting in pH<1. Second, under stirring, 0.485 g of BiNO₃*5H₂O is added to the solution. Third, the solution subsequently undergoes sonication for 10 minutes, until the solution achieves complete transparency. Fourth, under stirring, 0.166 g of SeO₂ and 0.08 g of TeO₂ is added to the solution, followed by sonication for 10 minutes. Then, the mixture is subjected to a gentle purge with purified nitrogen gas for 60 minutes. This process effectively eliminates any dissolved oxygen present in the solution. During the deposition process, the bath temperature is consistently maintained at 60° C. For the Bi₂Se₃ and Bi₂Te₃ embodiments, the electrolyte solution may be adjusted accordingly (e.g., for the Bi₂Se₃ embodiment, using a suitable amount of SeO₂ in the fourth step; for the Bi₂Te₃ embodiment, using a suitable amount of TeO₂ in the fourth step; etc.).

After the deposition, the samples are gently washed with deionized water and are subsequently annealed in a nitrogen atmosphere at 300° C. for 3 hours. The fabricated thin films exhibit a uniform appearance and excellent adhesion to the FTO-coated glass substrate.

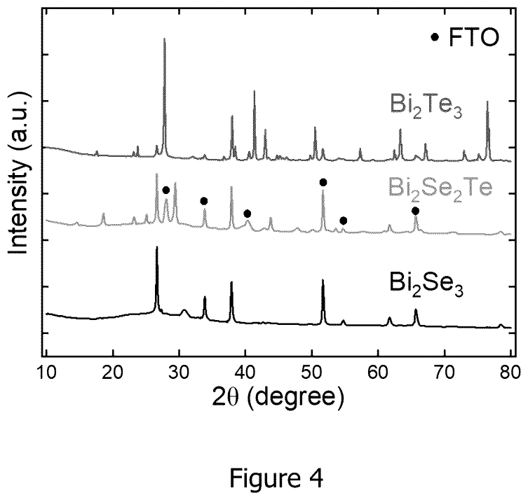

X-ray diffraction (XRD) analysis of the Bi₂Se₃, Bi₂Te₃, and Bi₂Se₂Te thin films in these embodiments is performed using a Rigaku Miniflex diffractometer. FIG. 4 shows the XRD analysis results.

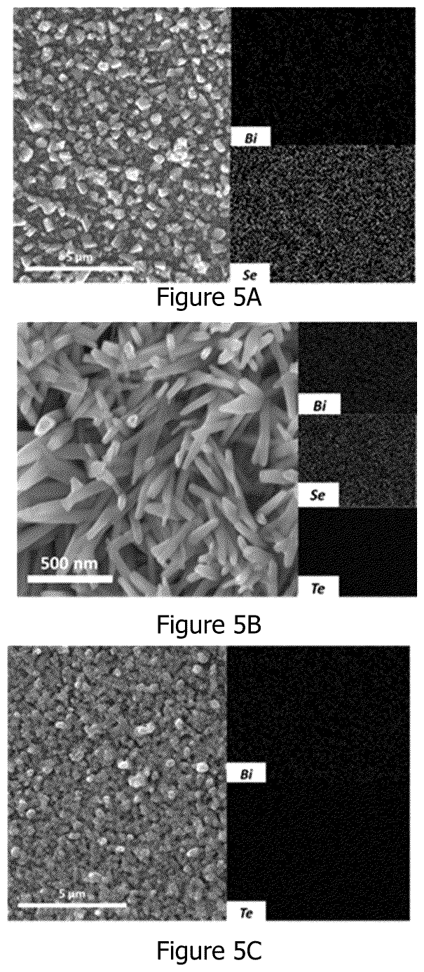

The surface morphology of the Bi₂Se₃, Bi₂Te₃, and Bi₂Se₂Te thin films in these embodiments is obtained using the Hitachi SU8240 field emission scanning electron microscope (FE-SEM). FIG. 5A shows the FE-SEM micrograph of the Bi₂Se₃ thin film and its elemental mapping distribution. FIG. 5B shows the FE-SEM micrograph of the Bi₂Se₂Te thin film and its elemental mapping distribution. FIG. 5C shows the FE-SEM micrograph of the Bi₂Te₃ thin film and its elemental mapping distribution.

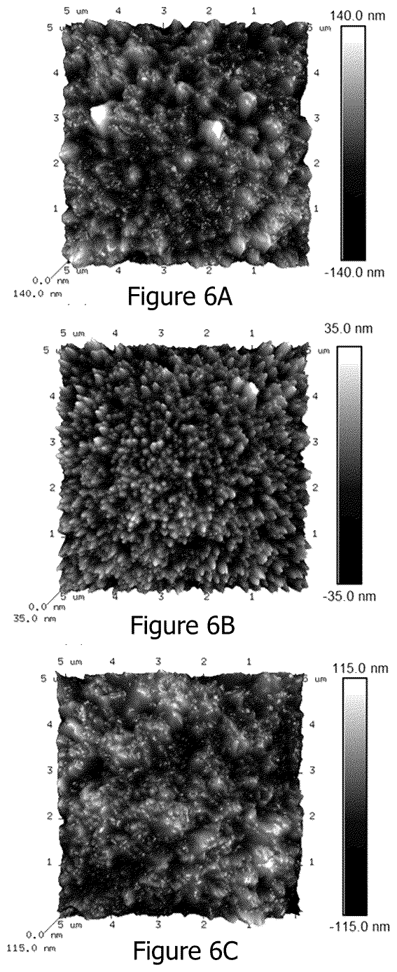

The roughness topography/surface roughness of the Bi₂Se₃, Bi₂Te₃, and Bi₂Se₂Te thin films in these embodiments is obtained using the Bruker Dimension HPI AFM (scan rate 0.996 Hz). FIG. 6A shows the AFM profile of the Bi₂Se₃ thin film. FIG. 6B shows the AFM profile of the Bi₂Se₂Te thin film. FIG. 6C shows the AFM profile of the Bi₂Te₃ thin film.

Measurement of carrier density and mobility are performed at room temperature using the Lakeshore Hall measurement system.

The quantum switching performance of synaptic devices can be determined based on the change in device resistance states, obtained from current-voltage (I-V) characteristics.

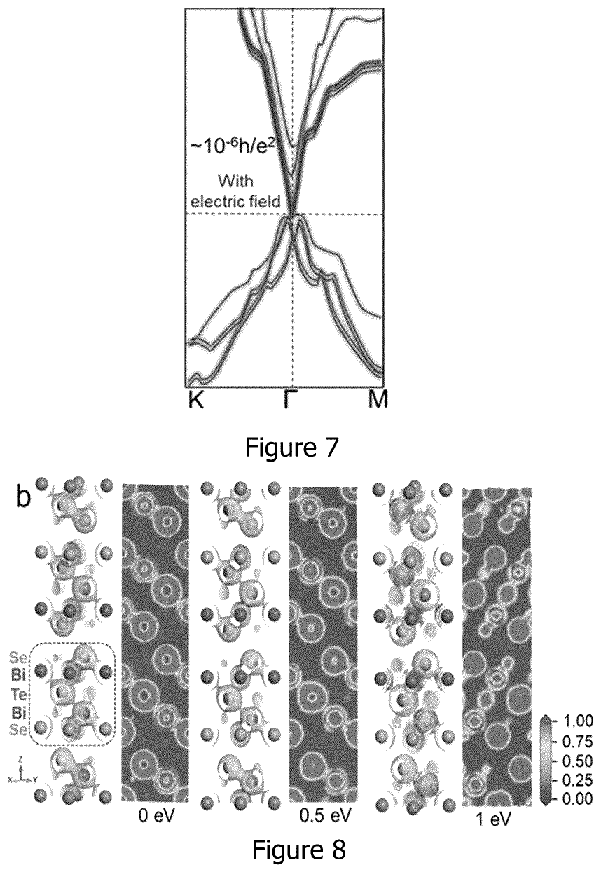

FIG. 7 illustrates a mechanism involved in the switching process, i.e., the topological surface edge state changes induced by an applied electric field, in Bi₂Se₂Te in one embodiment. FIG. 7 shows the surface edge states of Bi₂Se₂Te with a band gap. The initial surface edge states in Bi₂Se₂Te demonstrate a quantum resistance level of ~h/e², which, under the influence of an exerted internal electric field induced by the trapped charge densities, results in a higher order of conduction, in the order of 10⁻⁶ h/e². This higher order of conduction is attributed to an increased charge trap density, causing the formation of additional topological edge states owing to the strong spin Hall effect.

FIG. 8 illustrates a simulated charge density distribution in conduction band minimum and electron localization along the [100] plane of Bi₂Se₂Te under different applied electric fields in one embodiment. Specifically, FIG. 8 shows the change in charge density distribution in the conduction band and the electron localization along the [100] plane at different applied electric fields (0 eV, 0.5 eV, 1.0 eV). It can be seen that the charge distribution and electron localization for Bi₂Se₂Te show a prominent increase in levels. This indicates the mechanism of a trap-charge-induced internal electric field.

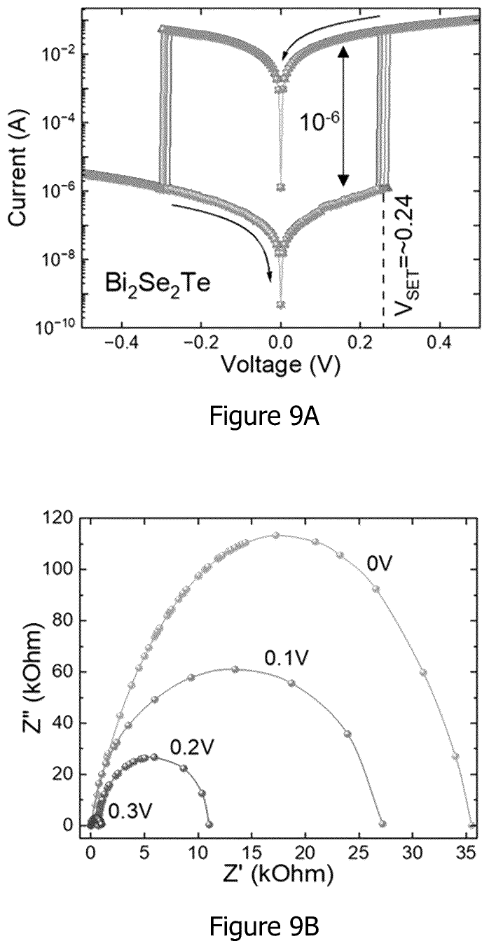

Following this mechanism, in a Bi₂Se₂Te synaptic device (synaptic device with Bi₂Se₂Te as active material between Ag and FTO electrodes, such as synaptic neuroelectronic device 200) in one embodiment, under the influence of an applied voltage stimulus, the trapped charge density increases, and an internal electric field is induced to enhance edge state conduction. This leads to ultra-low voltage synaptic switching properties. FIG. 9A illustrates the ultra-low threshold I-V switching characteristics of Bi₂Se₂Te in this embodiment, wherein the threshold voltage is about 0.24 V.

To illustrate the change in the resistance state of the Bi₂Se₂Te synaptic device, an impedance analysis is performed. FIG. 9B illustrates the result. As shown in FIG. 9B, as the applied voltage stimulus increases, the impedance level of the Bi₂Se₂Te synaptic device drops significantly. These characteristic results support the development of high-performance, low-power topological neuroelectronic quantum devices. These advantageous properties of quantum switching may be particularly suitable for synaptic devices.

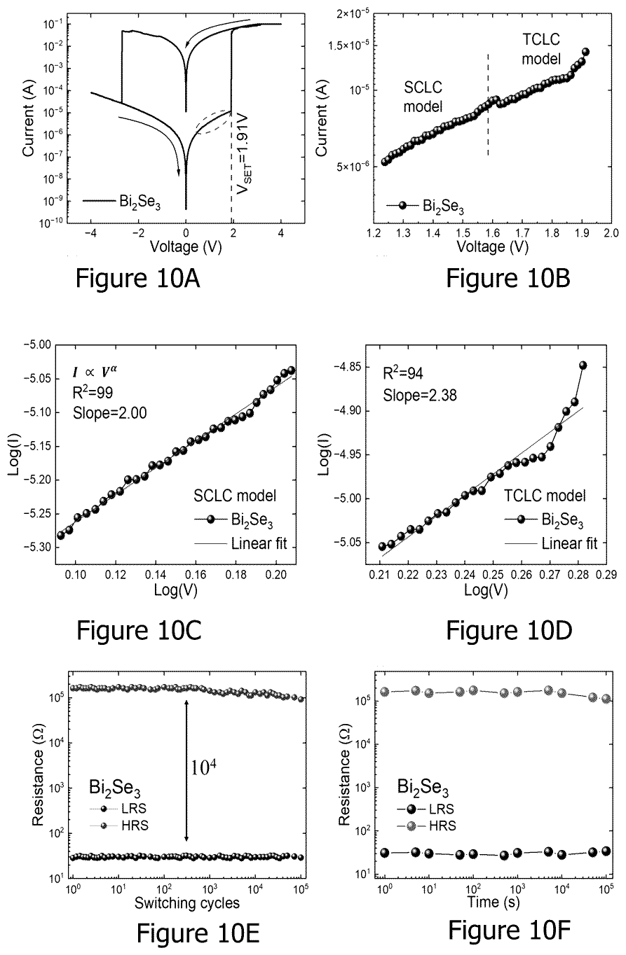

FIGS. 10A to 10F illustrate the conduction mechanisms and electrical characteristics for a Bi₂Se₃ synaptic device (synaptic device with Bi₂Se₃ as active material between Ag and FTO electrodes) in one embodiment. Specifically, FIG. 10A shows the resistive switching characteristics of the synaptic device, FIG. 10B shows the transition from high resistance state (HRS) to low resistance state (LRS) with different conduction mechanism regions for the synaptic device, FIG. 10C shows the synaptic switching current induced by the accumulation of charges in the active layer following the space charge limited current (SCLC) conduction mechanism, FIG. 10D shows the trapped charge limited current (TCLC) induced switching stage leading to the change in resistance state of the synaptic device, FIG. 10E shows the measure of the resistance of high resistance state (R_{HRS}) and the resistance of low resistance state (R_{LRS}) versus switching cycles, which indicate the endurance and on/off ratio performance of the synaptic device, and FIG. 10F shows the charge retention stability in the synaptic device with respect to time.

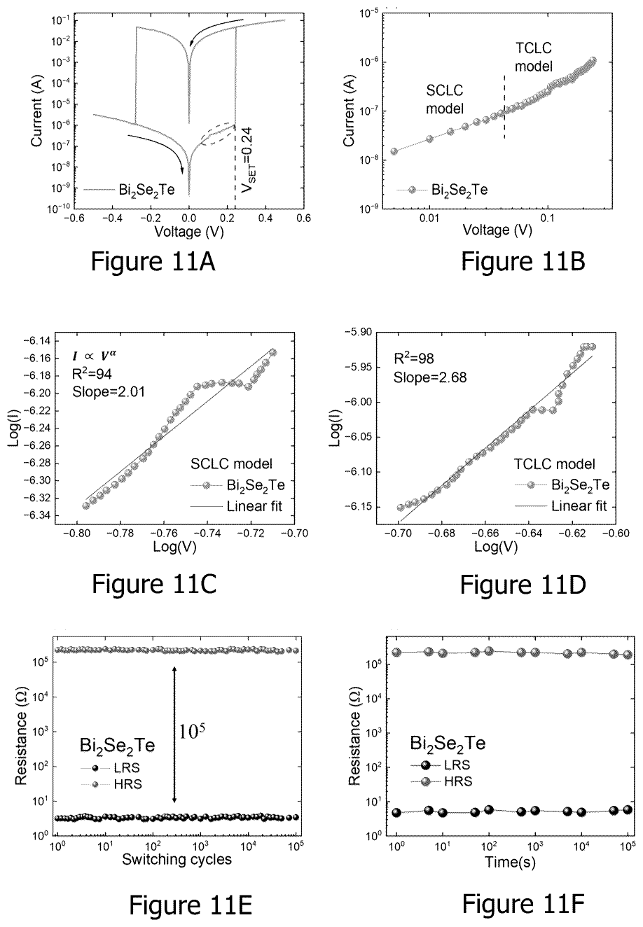

FIGS. 11A to 11F illustrate the conduction mechanisms and electrical characteristics for a Bi₂Se₂Te synaptic device (synaptic device with Bi₂Se₂Te as active material between Ag and FTO electrodes, such as synaptic neuroelectronic device 200) in one embodiment. Specifically, FIG. 11A shows the resistive switching characteristics of the synaptic device, FIG. 11B shows the transition from high resistance state (HRS) to low resistance state (LRS) with different conduction mechanism regions for the synaptic device, FIG. 11C shows the synaptic switching current induced by the accumulation of charges in the active layer following the space charge limited current (SCLC) conduction mechanism, FIG. 11D shows the trapped charge limited current (TCLC) induced switching stage leading to the change in resistance state of the synaptic device, FIG. 11E shows the measure of the resistance of high resistance state (R_{HRS}) and the resistance of low resistance state (R_{LRS}) versus switching cycles, which indicate the endurance and on/off ratio performance of the synaptic device, and FIG. 11F shows the charge retention stability in the synaptic device with respect to time.

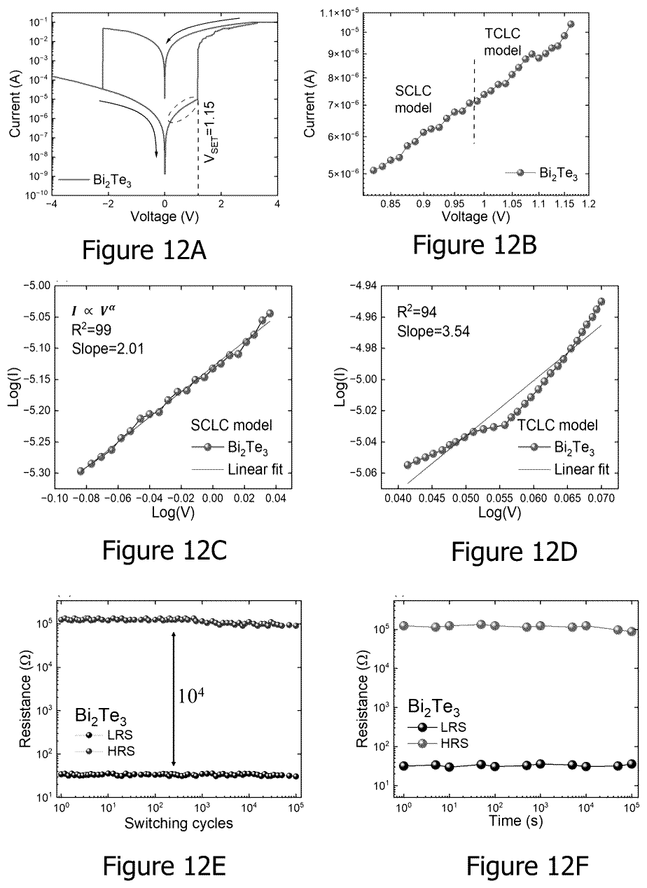

FIGS. 12A to 12F illustrate the conduction mechanisms and electrical characteristics for a Bi₂Te₃ synaptic device (synaptic device with Bi₂Te₃ as active material between Ag and FTO electrodes) in one embodiment. Specifically, FIG. 12A shows the resistive switching characteristics of the synaptic device, FIG. 12B shows the transition from high resistance state (HRS) to low resistance state (LRS) with different conduction mechanism regions for the synaptic device, FIG. 12C shows the synaptic switching current induced by the accumulation of charges in the active layer following the space charge limited current (SCLC) conduction mechanism, FIG. 12D shows the trapped charge limited current (TCLC) induced switching stage leading to the change in resistance state of the synaptic device, FIG. 12E shows the measure of the resistance of high resistance state (R_{HRS}) and the resistance of low resistance state (R_{LRS}) versus switching cycles, which indicate the endurance and on/off ratio performance of the synaptic device, and FIG. 12F shows the charge retention stability in the synaptic device with respect to time.

The quantum topological synaptic devices in some embodiments may be used as neuromodulators.

Biologically, neuromodulation in the human brain occurs through the release of event-specific neurotransmitters such as serotonin, dopamine, and acetylcholine. By the principle of Hebbian synaptic plasticity, upon receiving a request at a presynaptic point of a neuron, chemical messengers in the form of these neurotransmitters are released from the presynaptic membrane into the synaptic cleft and bind with their corresponding receptors at the postsynaptic membrane. This triggers an action potential as excitatory (EPSP) or inhibitory (IPSP) postsynaptic current to control the synaptic dynamics. If the membrane potential of the postsynaptic neuron is highly depolarized (+ve), the EPSP is generated with an increase in the firing rate at the postsynaptic neuron, causing a rise in their synaptic weight through spike-rate dependent plasticity (SRDP). On the other hand, a hyperpolarized (−ve) membrane potential causes a reduction in synaptic weight with respect to the level of IPSP response. Thus, the synaptic dynamics are directly modulated by the response level of EPSP and IPSP, causing potentiation or depression between two adjacent neurons or clusters during the neural event. Problematically, this biological process of neuromodulation in the human brain deteriorates exponentially with age. Thus, based on the biological neuromodulation process, it is useful to develop a synaptic neuromodulator that can address the deterioration.

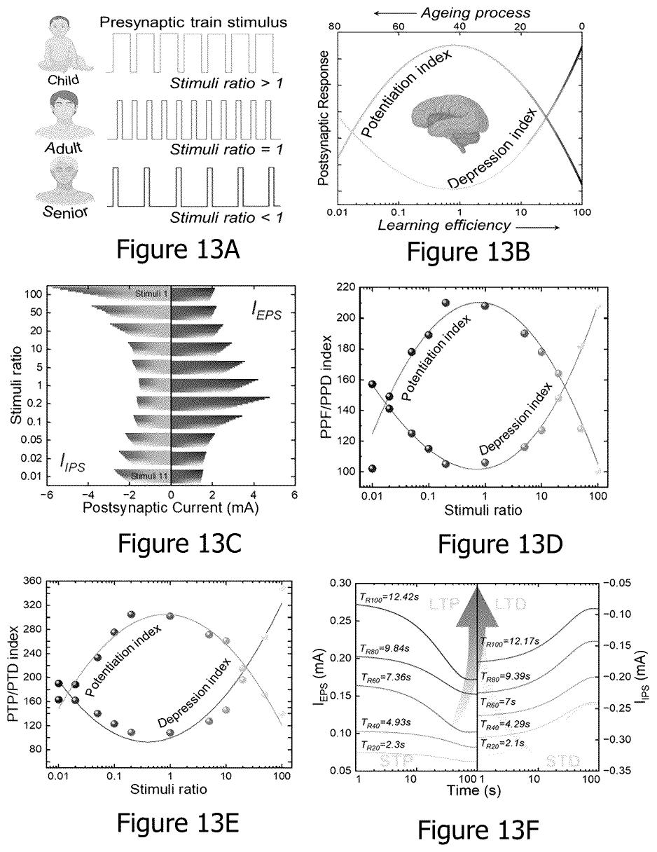

In one embodiment, there is provided a Bi₂Se₂Te synaptic device (synaptic device with Bi₂Se₂Te as active material between Ag and FTO electrodes, such as device 200) operable as a synaptic neuroelectronic device. The device may be referred to as a Bi₂Se₂Te based synaptic neuroelectronic device. The Bi₂Se₂Te based synaptic neuroelectronic device is operable to mimic the above described characteristics of neurotransmitters, and can demonstrate prominent synaptic SRDP behaviors with characteristic EPSP and IPSP responses as a function of applied pulse width modulated presynaptic electric stimuli. FIG. 13A shows the pulse width modulated presynaptic voltage stimuli, represented in terms of the stimuli ratio, for the Bi₂Se₂Te based synaptic neuroelectronic device.

This example defines the age-related postsynaptic response to an applied presynaptic stimulus, expressed in terms of the stimuli ratio. For a stimuli ratio larger than 1, it relates to the neural activity of early ages (child); for a stimuli ratio equals to 1, it relates to the neural activity of mid-age range (adult); and for a stimuli ratio less than 1, it denotes a decline in the synaptic neural response in elderly individuals. Based on these presynaptic stimuli ratio classifications, the characteristic behavior of the human brain with respect to the aging process and their corresponding learning efficiency are simulated. FIG. 13B shows the simulation results.

FIG. 13C illustrates an experimental postsynaptic current response of excitatory postsynaptic current (I_{EPS}) and inhibitory postsynaptic current (I_{IPS}) for different presynaptic stimuli ratios for the Bi₂Se₂Te based synaptic neuroelectronic device. As shown in FIG. 13C, for an applied presynaptic potentiation pulse stimulus, the I_{EPS} response is prominent only under the conditions of a stimuli ratio equal to 1 that represents the brains of mid-age people; for the younger (stimuli ratio >1) and older ages (stimuli ratio <1), the latency of I_{EPS} is larger. I_{IPS} responses for depressive stimuli are the exact inverse of I_{EPS}. This behavior in the Bi₂Se₂Te based synaptic neuroelectronic device is analogous to the biological synaptic response characteristics with respect to different ageing conditions. Moreover, the I_{EPS} and I_{IPS} responses are the important factors accountable for the neuromodulation of synaptic strengths to establish short-term and long-term neural plasticity.

Based on the postsynaptic current responses to the presynaptic stimuli, the PPF and PPD indexes, which are the quantification measures of short-term synaptic plasticity efficacies, are validated. The results are shown in FIG. 13D.

Based on the obtained PPF and PPD indexes, the results demonstrate a high level of efficacies for the short-term plasticity with respect to the applied stimuli ratios. The range of the PPF and PPD indexes indicates the ability of response to establish synaptic strength levels between presynaptic transmitters and postsynaptic receptors. As shown in FIG. 13D, in terms of stimuli ratio, the index for potentiation pulse stimuli for mid-age human brain (i.e., stimuli ratio≈1) is at the highest whereas for the early-age and elderly human brain (i.e., stimuli ratio >1 and stimuli ratio <1 respectively), the ability to respond to establish synaptic plasticity are under-developed and distorted, respectively. In this embodiment, the Bi₂Se₂Te based synaptic neuroelectronic device is a two-terminal device with a Bi₂Se₂Te active layer, and it has a maximum PPF index of 210% and a Δt (defined below) of 10 ms. For the event of presynaptic depression pulse stimuli, the PPD index demonstrates an increasing trend for larger stimuli ratios (>1). Thus, the PPF and PPD indexes of the Bi₂Se₂Te based synaptic neuroelectronic device illustrates the simulation response of short-term neural plasticity characteristics of human brain under age-related conditions. This characteristic behavior in the Bi₂Se₂Te based synaptic neuroelectronic device illustrates the capability of the device to modulate or override the responses owing to ageing or neural disorders in human brain, which can be defined as the process of neuromodulation.

The efficacies of synaptic plasticity strength are associatively quantified via the PTP and PTD indexes. FIG. 13E illustrates the results. As the PTP and PTD efficacies play a crucial role in determining short-term synaptic plasticity, the PTP and PTD indexes exhibit similar trends, serving as a longer-lasting neural facilitation function in the Bi₂Se₂Te based synaptic neuroelectronic device. Equipped with these capabilities, the Bi₂Se₂Te based synaptic neuroelectronic device can operate as a powerful neuromodulator. The Bi₂Se₂Te based synaptic neuroelectronic device may be used for BCIs, enabling the tuning and repair of age-related damages and neural disorders in the human brain through the control of presynaptic pulse width modulated stimuli.

The ability to retain the short-term or long-term neural plasticity weighted path is one of the main criteria for a healthy memory system, which governs cognitive functions. To understand these abilities in the Bi₂Se₂Te based synaptic neuroelectronic device, the human brain model proposed by Atkinson and Shiffrin, where the fundamental understanding of memorization events is facilitated through rehearsal learning, is adopted. The efficacies of the transition from short-term to long-term plasticity in the Bi₂Se₂Te based synaptic neuroelectronic device are examined through the estimation of relaxation times for I_{IPS} and I_{EPS} levels, with respect to applied stimuli. FIG. 13F shows the results. The results imply that increasing the applied stimuli from 20 to 100 pulse trains may cause exponential enhancements in the relaxation time (T_{R}), which directly corresponds to the strength of the synaptic weighted path. In this embodiment, the relaxation time T_{R} is calculated by the relation: I=I₀+Ae^{-T}^{_{R}}^{/τ}, where A is a constant, I₀ is a current constant, and τ is a relaxation constant. This characteristic increase in synaptic path weight or strength, observed for both potentiation and depression pulse stimuli in the Bi₂Se₂Te based synaptic neuroelectronic device, denotes the transition from short-term to long-term neural plasticity. However, this condition applies only to the stimuli ratio of 1 as the relaxation times for older and younger human brains diminish rapidly due to unstable synaptic neural responses.

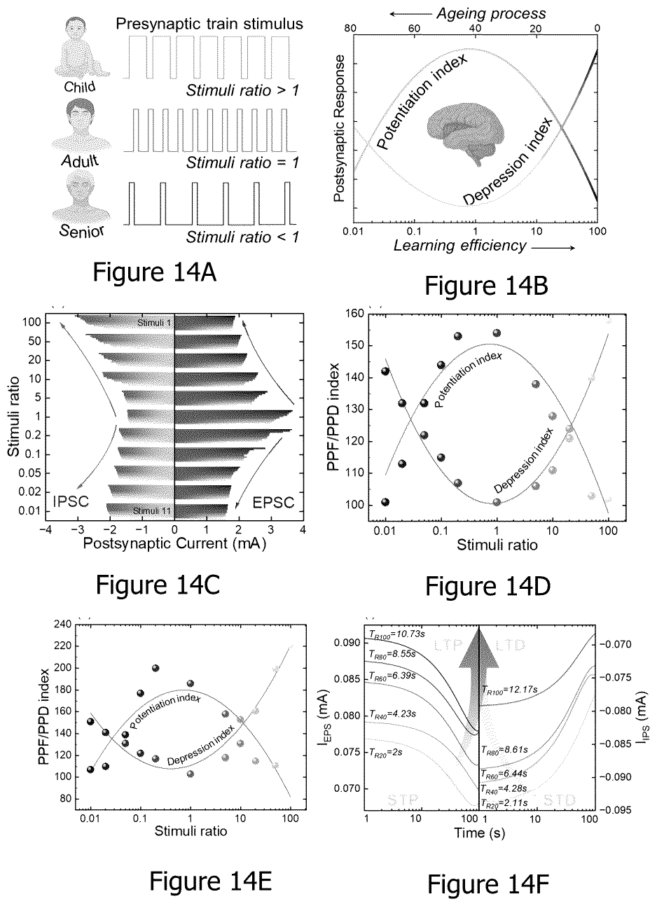

In one embodiment, there is provided a Bi₂Se₃ synaptic device (synaptic device with Bi₂Se₃ as active material between Ag and FTO electrodes) operable as a synaptic neuroelectronic device. The device may be referred to as a Bi₂Se₃ based synaptic neuroelectronic device. The Bi₂Se₃ based synaptic neuroelectronic device is the same as the Bi₂Se₂Te based synaptic neuroelectronic device in the above embodiment, except with the Bi₂Se₂Te active layer replaced with a Bi₂Se₃ active layer. FIGS. 14A to 14F illustrate the behaviour of the Bi₂Se₃ based synaptic neuroelectronic device with ageing-related presynaptic stimuli. FIGS. 14A to 14F generally correspond to FIGS. 13A to 13F, but is for the Bi₂Se₃ based synaptic neuroelectronic device not the Bi₂Se₂Te based synaptic neuroelectronic device. FIG. 14A shows the pulse width modulated presynaptic voltage stimuli, represented in terms of the stimuli ratio, for the Bi₂Se₃ based synaptic neuroelectronic device. FIG. 14B shows the postsynaptic response change with ageing process of human brain and their corresponding learning efficiency. FIG. 14C shows the experimental postsynaptic current response of I_{EPS} and I_{IPS} for for different presynaptic stimuli ratios for the Bi₂Se₃ based synaptic neuroelectronic device. FIG. 14D shows the PPF index and PPD index for different presynaptic stimuli ratios for the Bi₂Se₃ based synaptic neuroelectronic device. FIG. 14E shows the PTP index and PTD index for different presynaptic stimuli ratios for the Bi₂Se₃ based synaptic neuroelectronic device. FIG. 14F shows the synaptic transition from STP to LTP, represented in terms of relaxation time, for the Bi₂Se₃ based synaptic neuroelectronic device.

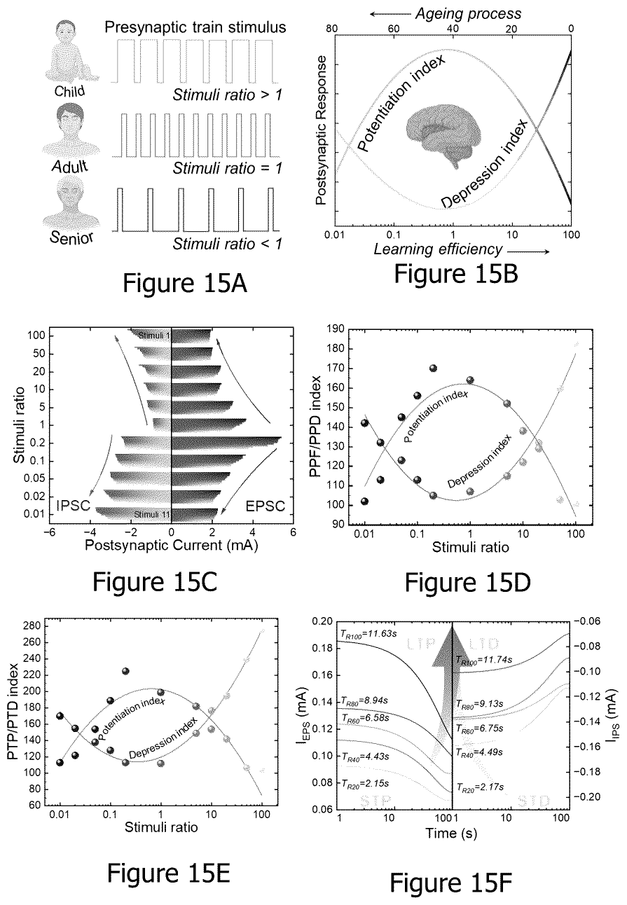

In one embodiment, there is provided a Bi₂Te₃ synaptic device (synaptic device with Bi₂Te₃ as active material between Ag and FTO electrodes) operable as a synaptic neuroelectronic device. The device may be referred to as a Bi₂Te₃ based synaptic neuroelectronic device. The Bi₂Te₃ based synaptic neuroelectronic device is the same as the Bi₂Se₂Te based synaptic neuroelectronic device in the above embodiment, except with the Bi₂Se₂Te active layer replaced with a Bi₂Te₃ active layer. FIGS. 15A to 15F illustrate the behaviour of the Bi₂Te₃ based synaptic neuroelectronic device with ageing-related presynaptic stimuli. FIGS. 15A to 15F generally correspond to FIGS. 13A to 13F, but is for the Bi₂Te₃ based synaptic neuroelectronic device not the Bi₂Se₂Te based synaptic neuroelectronic device. FIG. 15A shows the pulse width modulated presynaptic voltage stimuli, represented in terms of the stimuli ratio, for the Bi₂Te₃ based synaptic neuroelectronic device. FIG. 15B shows the postsynaptic response change with ageing process of human brain and their corresponding learning efficiency. FIG. 15C shows the experimental postsynaptic current response of I_{EPS} and I_{IPS} for for different presynaptic stimuli ratios for the Bi₂Te₃ based synaptic neuroelectronic device. FIG. 15D shows the PPF index and PPD index for different presynaptic stimuli ratios for the Bi₂Te₃ based synaptic neuroelectronic device. FIG. 15E shows the PTP index and PTD index for different presynaptic stimuli ratios for the Bi₂Te₃ based synaptic neuroelectronic device. FIG. 15F shows the synaptic transition from STP to LTP, represented in terms of relaxation time, for the Bi₂Te₃ based synaptic neuroelectronic device.

Though the conversion of the short-term to long-term neural plasticity can be realized via repeated rehearsal learning processes, an increase in the decay rate of the synaptic strength can lead to loss of memory. To overcome this phenomenon, in the synaptic devices operable as neuromodulators (e.g., those in some of the above embodiments), irrespective of these stimuli ratio conditions, modulation of the stimuli potential may tune the relaxation times.

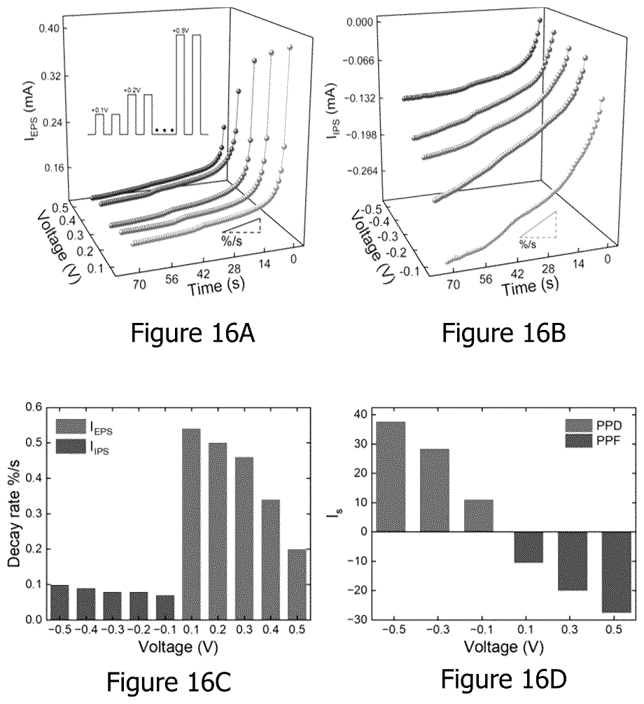

FIGS. 16A to 16D illustrate the pulse amplitude modulated synaptic strength tuning in a Bi₂Se₂Te synaptic device (synaptic device with Bi₂Se₂Te as active material between Ag and FTO electrodes, such as device 200) in one embodiment. Specifically, FIG. 16A shows the excitatory postsynaptic current relaxation time (decay rate) for different pulse amplitudes (0.1V, 0.2V, 0.3V, 0.4V, 0.5V) whereas FIG. 16B shows the inhibitory postsynaptic current relaxation time (decay rate) for different pulse amplitudes (−0.1V, −0.2V, −0.3V, −0.4V, −0.5V). FIG. 16C shows the auto-depression decay rate for pulse amplitude modulated presynaptic stimuli whereas FIG. 16D shows the correlation of EF-PPF for the change in synaptic strength which is calculated based on slope index levels.

As shown in FIGS. 16A and 16B, the decay rate (% s⁻¹) of the synaptic strengths increases with respect to the increase in the stimuli potential in both the cases of potentiation and depression presynaptic stimuli. The decrease in the decay rate indicates the ability to induce anti-ageing phenomenon in the Bi₂Se₂Te synaptic device. These properties are achieved via an edge state trapped-charged mechanism, where more charges are being accumulated or consumed in the developed additional topological edge states when potentiation or depression stimuli is applied.

As shown in FIGS. 16A and 16B, when applying the potentiation or depression stimuli is applied, the auto-depression behavior decreases due to the intensification of the charged-trapping effect, which enhances the synaptic path weightage or strength. FIG. 16C shows the declining decay rates for the respective response of the I_{EPS} and I_{IPS} levels. Thus, with an optimum voltage level, reversal of the ageing process in human brain can be accomplished via neuromodulating the decay rate of the synaptic strengths.

However, as PPF indexes are a preliminary factor for modulating synaptic strength from short-term to long-term, it would be useful to correlate changes in the PPF index with changes in amplitude-modulated synaptic pulse stimuli. To this end, electric field-dependent paired-pulse facilitation characteristics are investigated. The level of trapped charges in the Bi₂Se₂Te enhances the electric field, which directly corresponds to an increase in synaptic strength, thereby decreasing the decay rate in the Bi₂Se₂Te synaptic device. An increase in the internal electric field, owing to the trapped charge density in the Bi₂Se₂Te, leads to variations in the topological band structure, which can be expressed as:

$$n = \frac{1}{3 {π}^{2} {h}^{3}} {( \frac{2 {m}^{*} {e}^{2}}{4 π ε {ε}_{0}} )}^{3 / 2} {N}_{T}^{1 / 2} \qquad ( 1 )$$

where m* is the effective mass of the charge carrier and N_{T} is the charge trap density.

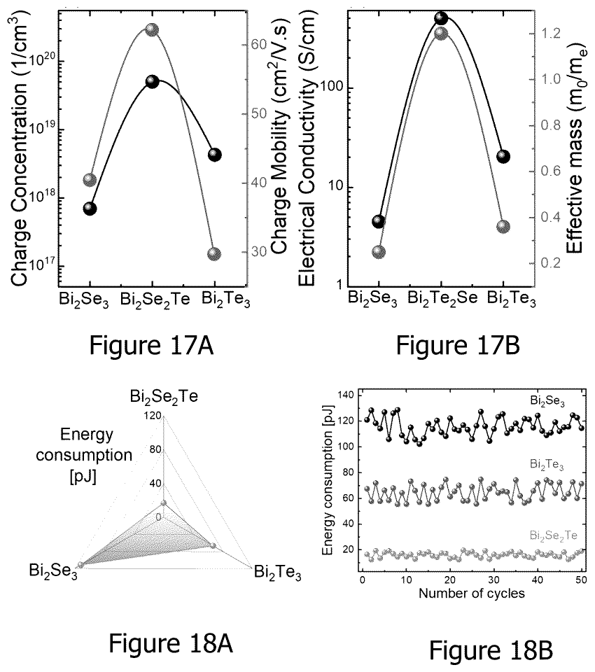

FIGS. 17A and 17B show the change in the carrier concentration and the effective mass with respect to the selenium ratios in one example.

In the human brain, the magnitude of the PPF function is directly related to age. As a person ages, the synaptic PPF index theoretically shows a consistent decrease in neural activities, leading to a gradual loss of communication strength between neighboring neurons. For elderly individuals, slower stimulus trains lead to a reduction in synaptic weight, which negatively affects the efficiency of learning activities. In contrast, young individuals achieve higher learning efficiency with a faster stimulus train rate. With similar characteristics, the synaptic neuromodulator devices in some of the above embodiments can mimic the learning activity of the human neural network for both elderly and young individuals.

FIG. 16D shows a related result. In FIG. 16D, the EF-PPF properties of the synapse are determined via the slope index (I_{S}), which quantifies the PPF index according to the equation PPF=(Δt)^{(I}^{_{S}}^{/100)}. As shown in FIG. 16D, positive I_{S} increases as the magnitude of the negative bias (voltage) increases whereas negative I_{S} decreases as the magnitude of the positive bias (voltage) increases. This flexibility in EF-PPF demonstrates a direct correlation between the interval of rehearsal events and learning efficiency under various voltage biases, demonstrating the ability of the Bi₂Se₂Te synaptic device in mimicking the neural plasticity of the human brain. Thus, by decreasing the decay rate or increasing synaptic strength via amplitude-modulated presynaptic pulse stimuli, faster learning and enhance memory longevity may be achieved.

As discussed above, various synaptic switching and neuromorphic characterization have been performed for the synaptic devices operable as neuromodulators or neuroelectronic devices in the above embodiments. In the above examples, the electrical characterization and switching properties of the devices are performed utilizing a probe station equipped with an Agilent Technologies B1500A Semiconductor Device Analyzer. The digital storage oscilloscope is used for data acquisition. Synaptic switching properties are examined and verified by applying the sequential sweep voltages to the synaptic devices to obtain I-V characteristics. SRDP is investigated by applying a series of ten consecutive pulse stimuli to the presynaptic neuron. The stimulus pattern is characterized in relation to the stimuli ratio, represented as a function of the pulse width. The pulse amplitude is fixed at +100 mV/−100 mV throughout the measurement in the above examples. The resulting I_{IPC} and I_{EPC} responses are measured and subjected to comprehensive analysis. PPF and PPD are analyzed by applying two consecutive pulse stimuli to the presynaptic neuron with relation to the stimuli ratio, represented as a function of the pulse width. The pulse amplitude is fixed at +100 mV/−100 mV throughout the measurement. By evaluating the postsynaptic current response to the predefined stimuli, the PPF and PPD indexes are calculated, providing a quantitative representation of short-term synaptic plasticity. The PPF and PPD indexes are determined using the following formula PPF or PPD index=A₂/A₁, where A₁ and A₂ represent the postsynaptic current responses elicited by the first and second pulses, respectively. PTP and PTD are investigated by applying ten consecutive pulse stimuli with a predefine stimuli ratio (as a function of the pulse width) to the presynaptic neuron. The pulse amplitude is fixed at +100 mV/−100 mV throughout the measurement in the above examples. Through the evaluation of the postsynaptic current response to the applied stimuli, the PTP and PTD indexes are calculated, serving as a quantitative measure of short-term synaptic plasticity. The PTP and PTD indexes are determined using the following formula PTP or PTD index=A₁₀/A₁, where A₁ and A₁₀ represent the postsynaptic current responses elicited by the first and second pulses, respectively. The transition process from short-term potentiation/depression (STP/STD) to long-term potentiation/depression (LTP/LTD) is examined and verified by applying a sequence of the consecutive presynaptic pulse stimuli, consisting of 20, 40, 60, 80, and 100 pulses respectively. The pulse amplitude is fixed at +100 mV/−100 mV throughout the measurement. The obtained results are subjected to fitting and analysis using an exponential equation that is commonly utilized as a forgetting function in psychology. The formula, expressed as (I=I₀+Ae^{-t/τ}) is employed, where A represents a constant amplitude, I₀ represents a constant current, and τ measures the relaxation constant, reflecting the rate of decay, which is the value of interest. Synaptic strength tuning (auto-depression rate) characteristic of the synaptic device is directly influenced by the temporal evolution of synaptic strength, a parameter intricately connected to age-related neuroplastic changes within the brain. This property is investigated through the application of five groups, each comprising 20 consecutive pulse stimuli to the presynaptic neuron. The stimuli are administered with a fixed pulse interval of 100 ms, a pulse width of 100 ms, and a pulse amplitude range from −0.0/0.1V to −0.5/0.5V. The time-dependent synaptic plasticity is examined, and the auto-depression rate is measured and extracted at intervals of 70 s. A comprehensive statistical analysis of 50 devices further corroborates the trends described above. The minimal variation observed between devices could be attributed to the uniformity of the thin films fabricated via the electrochemical deposition technique. Unlike conventional inorganic, organic, and oxide-based synaptic devices, the topological insulator based synaptic devices in some of the above examples can achieve exceptional synaptic switching performance of ≈10⁻⁶ s and a remarkably low energy consumption level of ≈17 pJ.

FIGS. 18A and 18B further show the energy consumption for quantum switching in some embodiments. Specifically, FIG. 18A shows the comparison of standardized energy consumption for the synaptic devices with Bi₂Se₂Te, Bi₂Te₃, and Bi₂Se₃ as active layers respectively in some of the above embodiments whereas FIG. 18B shows data driven measurement set for reliability in energy consumption for the synaptic devices with Bi₂Se₂Te, Bi₂Te₃, and Bi₂Se₃ as active layers respectively in some of the above embodiments.

In one synaptic device embodiment, the electrodes are Ag electrodes and FTO electrodes and the active layer operably coupled between the electrodes is Bi₂Se₃. The energy consumption of the device is 112×10⁻¹² J and the switching speed of the device is 4.80×10⁻⁶ s. In one synaptic device embodiment, the electrodes are Ag electrodes and FTO electrodes and the active layer operably coupled between the electrodes is Bi₂Te₃. The energy consumption of the device is 67×10⁻¹² J and the switching speed of the device is 5.35×10⁻⁶ s. In one synaptic device embodiment, the electrodes are Ag electrodes and FTO electrodes and the active layer operably coupled between the electrodes is Bi₂Se₂Te. the energy consumption of the device is 17×10⁻¹² J and the switching speed of the device is 7.68×10⁻⁶ s.

The synaptic devices in some embodiments may be used for real-time neuromodulation of electroencephalography (EEG) for BCI.

As a proof of concept, in one example, the synaptic neuroelectronic device 200 of FIG. 2 is applied to illustrate the neuromodulation of aging-distorted ERP signals deduced from EEG signals of a group of elderly individuals collected during auditory-cued reaction time tasks. ERPs are the measure of voltage change in the human brain followed by visual, auditory, or sensory stimuli.

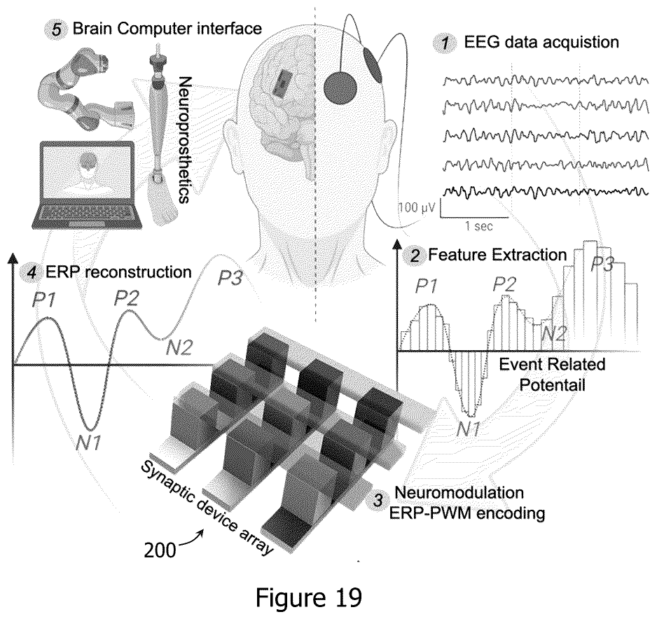

FIG. 19 shows the real-time modulation of EEG to ERPs neural signals using the synaptic neuroelectronic device 200 in one embodiment. In FIG. 19, the neuromodulation process includes: (1) EEG data acquisition, (2) ERPs feature extraction and signal sampling, (3) neuromodulation using the synaptic device, (4) ERP signals reconstruction, and (5) brain computer interfacing as neuro-prosthetic controls. As shown in FIG. 19, the characteristic ERP components are represented with P1/N1 regions around 0 to 100 ms, N2 region around 200 to 300 ms, P3 region between 300 and 500 ms, and N4 region between 400 and 600 ms. These characteristic components represent sensory stimuli processing (P1/N1), attentional monitoring (N2), memory and decision-making processes (P3), and semantic processing (N4), respectively. From deduced ERPs, the neural activities can be understood to assess the functional health levels of the brain in individuals affected by aging-related, Alzheimer's, or Parkinson's diseases.

It has been found that, with respect to brain aging, the levels of attenuation in P3 and N4 components are usually significantly distorted, causing major cognitive dysfunctions. Thus, modulating the ERPs with an effective modulation index can be particularly useful for brain-computer interfaces in assisting applications such as neuro-prosthetics, epilepsy management, treating memory impairments in elderly individuals, etc. Accordingly, the synaptic neuroelectronic device 200 is applied to demonstrate real-time neuromodulation of distorted ERPs to establish bidirectional communication as a brain-machine interface.

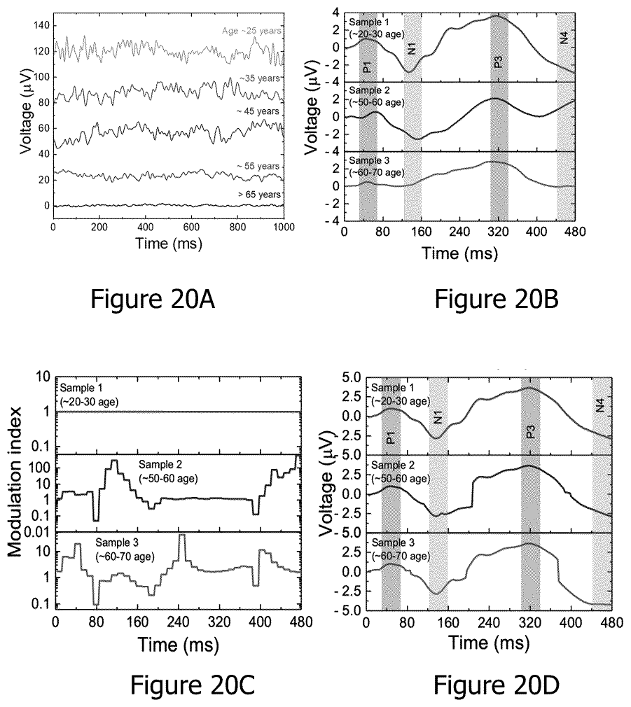

FIG. 19 demonstrates the mechanism of the neuromodulation process through the steps of EEG acquisition and processing, ERP component extraction, ERP-PWM encoding and neuromodulation (using the synaptic neuroelectronic device 200), and feedback. In an example real-time study, EEG datasets are collected from individuals of different age groups. FIG. 20A illustrates the EEG datasets in one example. ERPs are extracted from the EEG datasets, as shown in FIG. 20B. In the analysis in this example, an auditory cue reaction time tasks dataset of 39 ERPs belonging to elderly individuals aged in the range of 55 to 75 years and a reference ERP from a young individual is interpreted. The raw ERPs obtained from elderly individuals illustrate an increase in the distortion of P3 and N4 components compared to the reference signal, as shown in FIG. 20B. However, the process of modulating a neural signal requires intelligent event-specific signal modulation, which can only be performed through the training of neuromorphic synaptic devices. In this case, the modulation index or factor is obtained from the ratio of the change in conductance to the reference conductance in the synaptic neuroelectronic device 200, as shown in FIG. 20C.

In this example, to obtain the modulation index, the raw ERP dataset is processed into pulse width modulated signals via sampling, similar to the illustration in FIG. 19, which is then applied as pulse stimuli to the synaptic device. Further, the neuromodulated signals are developed using the modulation index together with the real dataset to make them recognizable without additional resources. This modulation boosts ERPs to similar strengths as the reference ERPs for every representative peak component, as shown in FIG. 20D. From this process, neuromodulated ERPs for any specific task can be obtained for brain-computer interface applications.

In the above example, publicly available EEG datasets from OpenNeuro are used. Specifically, in the above experiment, an EEG dataset associated with auditory cue reaction time tasks is selected, and used to subsequently derive further ERP signals. Out of 39 elderly individuals, aged between 55 and 75 years, five distinctive ERPs are selected for further in-depth analysis. As a reference point, a sample consisting of a young individual demonstrating optimal brain function is selected. 64 channels of EEG signals with an acquisition rate of 500 Hz are provided in the dataset. From all the EEG channels, FCz electrode closely relates to the cognitive processes. The raw EEG signals for each person are filtered by a band-pass filter with cutoff frequencies of 0.1 to 30 Hz, after which, ICA (independent component analysis) is applied to remove the artifacts from eyes and muscles. The pre-processed EEG signals for individuals are then segmented by the onset of the event and the event-related parts of the EEG signals are averaged to calculate the ERPs. After that, the ERPs are sampled every 12 ms to get event-related pulses as the inputs of the device 200 for further modulation.

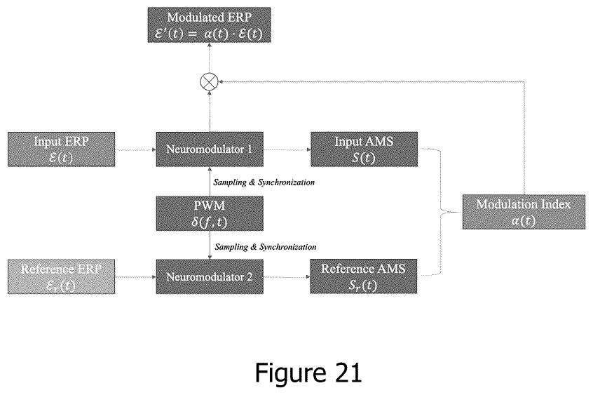

FIG. 21 shows a mathematical modelling of the neuromodulation in the above embodiment. Details of the mathematical modelling in one embodiment are as follows.

Assuming that the device 200 (used to modulation of EEG to ERP signals) is operating on a fundamental frequency fand the ERP that is received over time is E (t), the procedure of ERP modulation based on a reference ERP, E, (t), can be illustrated in the following steps:

First, ERP ε(t) is converted into an amplitude-modulated square wave (AMS) signal S(t), which is expressed as:

$$S ( t ) = ℰ ( t ) \times δ ( f , t ) \qquad ( 2 )$$

where δ(f, t) is a PWM function operating at frequency f, producing output values of 1 or 0 in each cycle.

Likewise, the AMS of reference ERP is expressed as Sᵣ(t)=εᵣ(t)×δᵣ(f, t), in which the PWM function is identical to the one used in S(t), enabling the alignment of S(t) and Sᵣ(t). Further, the modulation index α(t), which represents how much the received ERP should be modulated to fit with the reference ERP, is calculated by the AMS as:

$$α ( t ) = \{ \begin{matrix}\frac{\vert {S}_{r} ( t ) \vert}{\vert S ( t ) \vert} , & if t ∈ {t}_{on} \\ α ( t - 1 ) , & if t ∈ {t}_{off}\end{matrix} \qquad ( 3 )$$

where tₒₙ and t_{off} are the on and off periods of the PWM δ(f, t). Subsequently, α(t) is applied back to the original ERP received by the device 200 to obtain the modulated ERP ε′(t)=α(t)×ε(t).

The whole procedure of the modulation can be expressed as:

$${ℰ}^{′} ( t ) = \frac{\vert {ℰ}_{r} ( t ) \times δ ( f , t ) \vert}{\vert ℰ ( t ) \times δ ( f , t ) \vert} \times ℰ ( t ) \times [ t ∈ {t}_{on} ] + \frac{\vert {ℰ}_{r} ( t - 1 ) \times δ ( f , t - 1 ) \vert}{\vert ℰ ( t - 1 ) \times δ ( f , t - 1 ) \vert} \times ℰ ( t ) \times [ t ∈ {t}_{off} ] \qquad ( 4 )$$

where [t∈tₒₙ] and [t∈t_{off}] are the indicator functions that takes the value of 1 when the condition held true and the value of 0 when it is false.

Embodiments disclosed herein provide a synaptic device that includes one or more novel features and is useful for one or more applications. For example, in one embodiment, there is provided a QTI Bi₂Se₂Te-based synaptic neuroelectronic device for treating neurological disorders and for neuro-prosthetic applications. In one embodiment, there is provided a synaptic device with a unique performance in neuromodulation of brain signals as bidirectional communication for brain-computer interfaces. In one embodiment, there is provided a Bi₂Se₂Te synaptic neuroelectronic device that can mimic the synaptic neural behavior of the human brain, can provide characteristic response of postsynaptic potentials (PSPs), and which can be useful for the effective tuning of neural facilitation functions. In one embodiment, there is provided a synaptic neuroelectronic device with topological edge-state dependent quantum switching properties. In one embodiment, there is provided a synaptic neuroelectronic device with flexible neuromodulation behavior. In one embodiment, there is provided a synaptic neuroelectronic device that can be used for real-time neuromodulation of EEG derived event-related potentials of elderly individuals with cognitive dysfunctions for brain-computer interface applications. In one embodiment, there is provided a synaptic neuroelectronic device that utilizes the unique properties of QTI, such as Bi₂Se₂Te, which may represent a significant advancement in neuromorphic technologies, e.g., for brain-computer interfaced neuro-prosthetics. In one embodiment, there is provided a synaptic neuroelectronic device that can address aspects of power consumption (picojoules), data switching/processing speed (ms), and neuromorphic learning efficiency. These advantageous properties may arise from the transport characteristics of the electronic surface states of QTI (such as Bi₂Se₂Te) to achieve synchronous synaptic switching and a flexible PPF or PPD neuromodulation index that closely resembles the dynamics of biological neurons. In one embodiment, there is provided a synaptic neuroelectronic device that has flexible neuromodulation behavior, which may offer precise control capacity in the learning-to-forget process of the human brain to shape the electrophysiological activities. In one embodiment, there is provided a synaptic neuroelectronic device that can be used for real-time neuromodulation of EEG derived ERPs of elderly individuals with cognitive dysfunctions to match the healthy neural function of young individuals for brain-computer interface applications. In one embodiment, there is provided a synaptic neuroelectronic device that can provide controlled synchronization and achieve memory function longevity, hence may be used for mitigating the causes and impacts of aging and neurological disorders in humans.

It will be appreciated by one skilled in the art that variations and/or modifications may be made to the described and illustrated embodiments to provide other embodiments. The described and illustrated embodiments should therefore be considered in all respects as illustrative, not restrictive. For example, the application or use of the synaptic device is not limited to the example applications or uses disclosed herein. For example, the material of the first electrode may more generally include electrically conductive oxide such as but not limited to transparent conductive oxide. For example, the material of the second electrode may more generally include metal. For example, the material of the topological insulator is not limited to bismuth-based material. For example, the topological insulator may not be in the form of a thin film.

1. A synaptic device comprising:
a first electrode;
a second electrode; and
a topological insulator operably coupled between the first electrode and the second electrode.

2. The synaptic device of claim 1, wherein the topological insulator is a quantum topological insulator.

3. The synaptic device of claim 2, wherein the topological insulator is in a form of a thin film.

4. The synaptic device of claim 3, wherein the topological insulator is deposited or electroplated on the first electrode.

5. The synaptic device of claim 4, wherein the topological insulator comprises a bismuth-based topological insulator made of bismuth-based material, such as bismuth selenide telluride (Bi₂Se₂Te), bismuth selenide (Bi₂Se₃), or bismuth telluride (Bi₂Te₃).

6. The synaptic device of claim 1, wherein the topological insulator is made from a material comprising at least one of: bismuth selenide telluride (Bi₂Se₂Te), bismuth selenide (Bi₂Se₃), bismuth telluride (Bi₂Te₃), tin telluride (SnTe), tin selenide (SnSe), tin selenide telluride, (SnSeTe), antimony telluride (Sb₂Te₃), antimony selenide (Sb₂Se₃), antimony selenide telluride (SbSeTe), lead telluride (PbTe), lead selenide (PbSe), mercury telluride (HgTe), cadmium arsenide (Cd₃As₂) or any combination thereof.

7. The synaptic device of claim 6, wherein the first electrode comprises an electrical conductor made of an electrically conductive oxide.

8. The synaptic device of claim 7, wherein the electrically conductive oxide comprises transparent conductive oxide.

9. The synaptic device of claim 7, wherein the electrically conductive oxide comprises fluorine-doped tin oxide (FTO).

10. The synaptic device of claim 7, wherein the electrically conductive oxide is arranged on a substrate.

11. The synaptic device of claim 10, wherein the substrate comprises a glass substrate.

12. The synaptic device of claim 11, wherein the second electrode comprises an electrical conductor made of metal.

13. The synaptic device of claim 12, wherein the metal comprises silver.

14. The synaptic device of claim 6, wherein the synaptic device is a two-terminal synaptic device, with the first electrode emulating a postsynaptic terminal and the second electrode emulating a presynaptic terminal.

15. The synaptic device of claim 6, wherein the first electrode is arranged to emulate a postsynaptic terminal, the second electrode is arranged to emulate a presynaptic terminal, and the synaptic device is operable to neuromodulate synaptic response characteristics by dynamically adjusting a signal transmission efficiency between the presynaptic terminal and the postsynaptic terminal in response to receiving an applied stimulation signal.

16. The synaptic device of claim 6, wherein the synaptic device is operable to perform neuromodulation.

17. The synaptic device of claim 16, wherein:
the synaptic device is operable to dynamically adjust a synaptic conductance state for performing neuromodulation; and
the neuromodulation is performed based at least in part on a modulation index derived from a ratio between a change in synaptic conductance and a reference synaptic conductance.

18. The synaptic device of claim 6, wherein:
the synaptic device is operable to emulate a synaptic plasticity mechanism, and the synaptic plasticity mechanism comprises at least one of: paired-pulse facilitation (PPF), Paired-Pulse Depression (PPD), post-tetanic potentiation (PTP), post-tetanic depression (PTD), short-term plasticity (STP), short-term depression (STD), long-term potentiation (LTP), long-term depression (LTD), excitatory postsynaptic current (EPSC), inhibitory postsynaptic current (IPSC), or spike-rate dependent plasticity (SRDP).

19. The synaptic device of claim 6, wherein the synaptic device is operable to dynamically adjust synaptic weight in response to receiving a stimulation signal.

20. A synaptic device array comprising multiple ones of the synaptic device of claim 1.
